(19) United States
(12) Patent Application Publication
(10) Pub. No.: US 2025/0318243 A1
(43) Pub. Date: Oct. 9, 2025

(54) SEMICONDUCTOR DEVICE AND MANUFACTURING METHOD

(71) Applicants: Kabushiki Kaisha Toshiba, Tokyo (JP); Toshiba Electronic Devices & Storage Corporation, Tokyo (JP)

(72) Inventor: Masataka INO, Oita Oita (JP)

(21) Appl. No.: 18/882,662

(22) Filed: Sep. 11, 2024

(30) Foreign Application Priority Data
Apr. 3, 2024 (JP) 2024-060453

(51) Int. Cl. H01L 29/423; H01L 29/40; H01L 29/47; H01L 29/49

(52) U.S. Cl. CPC H10D 64/517; H10D 64/117; H10D 64/64; H10D 64/666

(57) ABSTRACT

A semiconductor device includes a first electrode, a second electrode disposed separately from the first electrode in a first direction, a control electrode disposed to face the second electrode in a second direction intersecting the first direction, a first insulating portion provided between the second electrode and the control electrode, a semiconductor layer provided between the first electrode and the second electrode, a first region provided between the second electrode and the first insulating portion in the semiconductor layer and connected to the second electrode by a Schottky junction, and a second region joined to the first region, disposed on the first electrode side, connected to the second electrode by a Schottky junction, and having a smaller width in the second direction than at least a part of the first region.

### CROSS REFERENCE TO RELATED APPLICATIONS

This application is based upon and claims the benefit of priority from the prior Japanese Patent Application No. 2024-060453, filed on Apr. 3, 2024, the entire contents of which are incorporated herein by reference.

### FIELD

Embodiments described herein relate generally to a semiconductor device and a manufacturing method.

### BACKGROUND

In a semiconductor device in which a height of a Schottky barrier is controlled by a voltage applied to a gate electrode to switch between an on state and an off state, a source contact resistance is preferably low.

### BRIEF DESCRIPTION OF THE DRAWINGS

FIG. 1 is a schematic cross-sectional view illustrating a semiconductor device according to an embodiment of the present disclosure;

FIG. 2 is an enlarged view of a pillar portion and a peripheral portion in FIG. 1;

FIG. 3 is a schematic diagram of a three-dimensional structure of the semiconductor device according to the embodiment of the present disclosure;

FIG. 4A is a diagram illustrating a process of forming a field plate of a semiconductor element according to the embodiment of the present disclosure;

FIG. 4B is a diagram illustrating a first oxidation process of a semiconductor layer of the semiconductor element according to the embodiment of the present disclosure;

FIG. 4C is a diagram illustrating a first film formation process of an insulating film of the semiconductor element according to the embodiment of the present disclosure;

FIG. 4D is a diagram illustrating a second film formation process of the insulating film of the semiconductor element according to the embodiment of the present disclosure;

FIG. 4E is a diagram illustrating a first etch-back process of the insulating film of the semiconductor element according to the embodiment of the present disclosure;

FIG. 4F is a diagram illustrating a first removal process of the insulating film of the semiconductor element according to the embodiment of the present disclosure;

FIG. 4G is a diagram illustrating a second removal process of the insulating film of the semiconductor element according to the embodiment of the present disclosure;

FIG. 4H is a diagram illustrating a second oxidation process of the semiconductor layer of the semiconductor element according to the embodiment of the present disclosure;

FIG. 4I is a diagram illustrating a third removal process of the insulating film of the semiconductor element according to the embodiment of the present disclosure;

FIG. 4J is a diagram illustrating a half etch-back process of the insulating film of the semiconductor element according to the embodiment of the present disclosure;

FIG. 4K is a diagram illustrating a process of forming a body region of the semiconductor element according to the embodiment of the present disclosure;

FIG. 4L is a diagram illustrating a third oxidation process of the semiconductor layer of the semiconductor element according to the embodiment of the present disclosure;

FIG. 4M is a diagram illustrating a process of forming a control electrode of the semiconductor element according to the embodiment of the present disclosure;

FIG. 4N is a diagram illustrating an etch-back process of the control electrode of the semiconductor element according to the embodiment of the present disclosure;

FIG. 4O is a diagram illustrating a process of forming a second insulating portion of the semiconductor element according to the embodiment of the present disclosure;

FIG. 4P is a diagram illustrating an etch-back process of an insulating portion of the semiconductor element according to the embodiment of the present disclosure;

FIG. 4Q is a diagram illustrating a first formation process of a mesa portion of the semiconductor element according to the embodiment of the present disclosure;

FIG. 4R is a diagram illustrating a second formation process of the mesa portion of the semiconductor element according to the embodiment of the present disclosure;

FIG. 4S is a diagram illustrating a fourth oxidation process of the semiconductor layer of the semiconductor element according to the embodiment of the present disclosure;

FIG. 4T is a diagram illustrating an impurity doping and thermal diffusion process of the semiconductor element according to the embodiment of the present disclosure;

FIG. 4U is a diagram illustrating a third film formation process of the insulating film of the semiconductor element according to the embodiment of the present disclosure;

FIG. 4V is a diagram illustrating a second etch-back process of the insulating film of the semiconductor element according to the embodiment of the present disclosure;

FIG. 4W is a diagram illustrating a process of forming a trench of the semiconductor element according to the embodiment of the present disclosure;

FIG. 4X is a diagram illustrating an etching process of the insulating portion of the semiconductor element according to the embodiment of the present disclosure;

FIG. 4Y is a diagram illustrating a metal film formation process of a first metal layer of the semiconductor element according to the embodiment of the present disclosure;

FIG. 4Z is a diagram illustrating a metal film formation process of a second metal layer of the semiconductor element according to the embodiment of the present disclosure;

FIG. 5A is a first diagram illustrating a configuration of a semiconductor device according to a comparative example; and

FIG. 5B is a second diagram illustrating the configuration of the semiconductor device according to the comparative example.

### DETAILED DESCRIPTION

A semiconductor device according to an embodiment of the present disclosure includes a first electrode, a second electrode disposed separately from the first electrode in a first direction, a control electrode disposed to face the second electrode in a second direction intersecting the first direction, a first insulating portion provided between the second electrode and the control electrode, a semiconductor layer provided between the first electrode and the second electrode, a first region provided between the second electrode and the first insulating portion in the semiconductor layer and connected to the second electrode by a Schottky junction, and a second region joined to the first region, disposed on the first electrode side, connected to the second electrode by a Schottky junction, and having a smaller width in the second direction than at least a part of the first region.

Hereinafter, embodiments according to the present invention will be described with reference to the drawings. The embodiments do not limit the present invention. The drawings are schematic or conceptual, and a ratio of each portion or the like is not necessarily the same as the actual. In the specification and the drawings, elements similar to those described above with respect to the previous drawings are denoted by the same reference numerals, and the detailed description thereof is appropriately omitted.

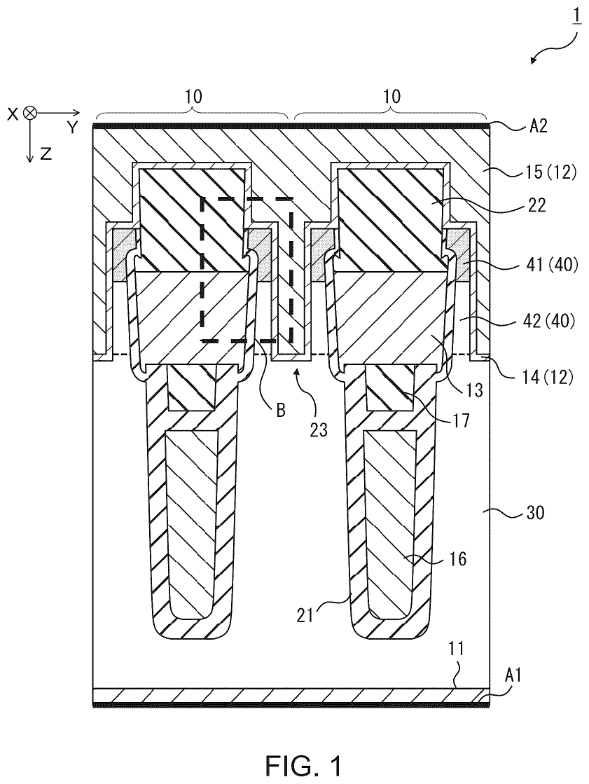

For convenience of description, an XYZ orthogonal coordinate system is adopted as illustrated in FIG. 1 and the like. A Z-axis direction is a stacking direction (thickness direction) of a semiconductor device. A Y-axis direction is one direction of a planar direction of the semiconductor device, and more specifically, is a direction in which a plurality of semiconductor elements are arranged. In a Z-axis direction, the source electrode side is also referred to as “upper”, and the drain electrode side is also referred to as “lower”. However, these expressions are for convenience and independent of a direction of gravity. In the present specification, the Z-axis direction, the Y-axis direction, and the X-axis direction are also referred to as a first direction Z, a second direction Y, and a third direction X, respectively.

In the following description, notations of n⁺, n, n⁻, and p⁺, p, and p⁻may be used to represent a relative level of an impurity concentration in each conductivity type. That is, n⁺has a relatively higher n-type impurity concentration than n, and n has a relatively lower n-type impurity concentration than n. In addition, p⁺has a relatively higher p-type impurity concentration than p, and p-has a relatively lower p-type impurity concentration than p. When both a p-type impurity and an n-type impurity are included in each region, these notations represent a relative level of a net impurity concentration after the impurities are compensated for. In the present specification, an n type, an n⁺type, and an n type are also referred to as a first conductivity type. In addition, in the present specification, a p type, a p⁺type, and a p-type are also referred to as a second conductivity type. In the following description, the n type and the p type may be reversed.

An impurity concentration of a semiconductor region can be measured by, for example, secondary ion mass spectrometry (SIMS). A relative level of the impurity concentration can also be determined from a level of a carrier concentration obtained by, for example, a scanning capacitance microscopy (SCM).

In addition, dimensions such as widths of a contact portion can be measured by, for example, analysis of a surface and/or a cross section by a transmission electron microscope (TEM), an energy dispersive X-ray spectroscopy (EDX), or a scanning electron microscope (SEM).

In addition, a composition of a conductive portion or the like can be analyzed by the energy dispersive X-ray spectroscopy or the like.

### Embodiment of Present Disclosure

FIG. 1 is a schematic cross-sectional view illustrating a semiconductor device 1 according to an embodiment of the present disclosure. The semiconductor device 1 of FIG. 1 includes one or a plurality of semiconductor elements 10. Each of the semiconductor elements 10 includes a first electrode 11, a second electrode 12, a control electrode 13, a first insulating portion 21, and a semiconductor layer 30. The semiconductor element 10 may further include a conductive portion 16, an interlayer film 17, and a second insulating portion 22.

The semiconductor element 10 according to the present embodiment is a vertical transistor. More specifically, the semiconductor element 10 is a vertical metal oxide silicon field effect transistor (MOSFET) that switches between an on state and an off state by controlling a thickness of a Schottky barrier by controlling a potential of a gate electrode (control electrode 13 to be described later).

A longitudinal direction and a lateral direction in FIG. 1 correspond to the first direction Z and the second direction Y, respectively.

The semiconductor layer 30 may be an epitaxial layer, a semiconductor substrate, or the semiconductor substrate and the epitaxial layer disposed on the semiconductor substrate. In the present specification, an example in which the semiconductor layer 30 is made of Si will be described. In this case, As, P, or Sb is used as an example of the n-type impurity (hereinafter, also referred to as a donor) doped in the semiconductor layer 30, and B is used as an example of the p-type impurity (hereinafter, also referred to as an acceptor). Note that the semiconductor layer 30 may be made of a compound semiconductor such as SiC or GaN.

The first electrode 11 is disposed on the first surface A1 side of the semiconductor layer 30. The first electrode 11 is electrically connected to the semiconductor layer 30. The first electrode 11 is made of, for example, Cu, Ti, W, Al, or the like. The first electrode 11 is, for example, a drain electrode of the semiconductor element 10.

The second electrode 12 is disposed separately from the first electrode 11 in the first direction Z. The second electrode 12 is disposed on the second surface A2 side of the semiconductor layer 30 and has a convex portion 23 extending toward the first surface A1. The second electrode 12 may further include a first metal layer 14 and a second metal layer 15 to be stacked. The second electrode 12 is, for example, a source electrode of the semiconductor element 10.

In the semiconductor element 10, the first electrode 11 may be the source electrode, and the second electrode 12 may be the drain electrode.

The first metal layer 14 contains a first metal element. The first metal element is, for example, at least one (for example, Co or Pt) of Ti, W, Mo, Ta, Zr, Al, Sn, V, Re, Os, Ir, Pt, Pd, Rh, Ru, Nb, Sr, Co, or Hf. The first metal layer 14 may be a metal layer doped with impurities.

The second metal layer 15 is disposed so as to cover the first metal layer 14. The second metal layer 15 contains a second metal element having a work function lower than that of the first metal element. The second metal element is, for example, at least one (for example, W) of Al, Cu, Mo, W, Ta, Co, Ru, Ti, or Pt.

The control electrode 13 is disposed to face the second electrode 12 (source electrode) in the second direction Y. The control electrode 13 is made of, for example, polysilicon. The control electrode 13 is, for example, a gate electrode of the semiconductor element 10 that controls a current flowing between the first electrode 11 and the second electrode 12.

The first insulating portion 21 is disposed between the control electrode 13 and the convex portion 23 of the second electrode 12. More specifically, the first insulating portion 21 is disposed so as to surround the control electrode 13, the interlayer film 17, and the conductive portion 16, and insulates the control electrode 13 and the semiconductor layer 30. The first insulating portion 21 is made of, for example, SiO₂. A part of the first insulating portion 21 is used as, for example, a gate insulating film.

The second insulating portion 22 is adjacent to the control electrode 13 and disposed on the second surface A2 side from the control electrode 13. More specifically, the second insulating portion 22 is disposed between the control electrode 13 and the second electrode 12, and insulates the control electrode 13 and the second electrode 12. The second insulating portion 22 is made of, for example, SiO₂.

The control electrode 13 and a part of the second insulating portion 22 form a cylindrical shape.

The semiconductor layer 30 is in contact with the first electrode 11 and is electrically connected to the first electrode 11. In the present specification, an example in which the semiconductor layer 30 includes an n-type (first conductivity type) semiconductor will be described, but the semiconductor layer 30 may include a p-type (second conductivity type) semiconductor.

The semiconductor layer 30 has a pillar portion 40 disposed between the convex portion 23 of the second electrode 12 and the first insulating portion 21. The pillar portion 40 has a first region 41 disposed on the second surface A2 side, and a second region 42 joined to the first region 41 and disposed on the first surface A1 side. The first region 41 and the second region 42 are connected to the first metal layer 14 in the second electrode 12 (source electrode) by a Schottky junction. The first region 41 is used as, for example, a source contact region. The second region 42 is used as, for example, a channel region.

The control electrode 13 can control a current flowing between the first electrode 11 and the second electrode 12. For example, a Schottky barrier is formed at an interface between the second electrode 12 and the second region 42, and a depletion layer is formed in the second region 42. A height of the Schottky barrier is controlled by the voltage applied to the control electrode 13, and a carrier concentration in the second region 42 is controlled. When the voltage of the control electrode 13 is equal to or less than a threshold voltage, no current flows between the first electrode 11 and the second electrode 12 via the second region 42, that is, the semiconductor element 10 is turned off. When the voltage of the control electrode 13 exceeds the threshold voltage, a current flows between the first electrode 11 and the second electrode 12 via the second region 42, that is, the semiconductor element 10 is turned on.

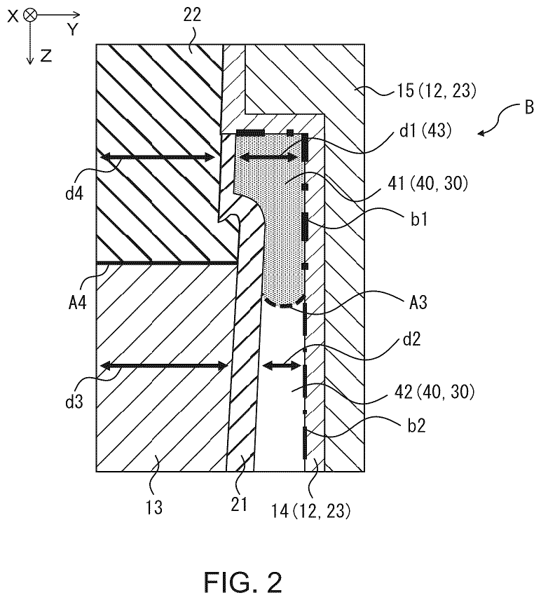

FIG. 2 is an enlarged view of a region B in FIG. 1. FIG. 2 illustrates the control electrode 13, the first insulating portion 21, the second insulating portion 22, the convex portion 23 of the second electrode 12, and the pillar portion 40 of the semiconductor layer 30.

As illustrated in FIG. 2, an interface A3 between the first region 41 and the second region 42 is provided closer to the first surface A1 (that is, the lower side of FIG. 2) than an interface A4 between the control electrode 13 and the first insulating portion 21.

As illustrated in FIG. 2, in the first region 41, a width d1 in the second direction Y of a part (region 43) of a portion facing the second insulating portion 22 is larger than a width d2 of the second region 42. As a result, a Schottky barrier b1 generated at an interface between the first region 41 and the first metal layer 14 can be made lower than a Schottky barrier b2 generated at an interface between the second region 42 and the first metal layer 14.

The region 43 can be formed, for example, by making a width d3 of the control electrode 13 in the second direction Y larger than a width d4 of at least a part of a portion of the second insulating portion 22 facing the second electrode 12 in the second direction Y, in other words, by forming a cylindrical shape with the control electrode 13 and a part of the second insulating portion 22.

By increasing the height of the Schottky barrier b2 of the second region 42, the threshold voltage of the semiconductor element 10 can be increased. As a result, the semiconductor element 10 can also be configured as a normally-off MOSFET. On the other hand, by decreasing the height of the Schottky barrier b1 of the first region 41, a source contact resistance of the semiconductor element 10 can be reduced, and an on-resistance of the semiconductor element 10 can be reduced. As a result, it is possible to realize high-speed switching of the semiconductor element 10, suppression of a turn-on loss, and suppression of a turn-off loss.

That is, as illustrated in FIG. 2, the Schottky barriers b1 and b2 can be adjusted by making the width d1 of the first region 41 larger than the width d2 of the second region 42. This makes it possible to achieve both an increase in the threshold voltage of the semiconductor element 10 and a reduction in the on-resistance.

The Schottky barriers b1 and b2 can also be adjusted by impurities doped in the first region 41 and the second region 42.

The first region 41 and the second region 42 are doped with impurities (donors), respectively. The impurities doped in the first region 41 and the second region 42 are, for example, at least one (for example, As) of As, P, Sb, or Mg. When the semiconductor layer 30 is a p-type semiconductor, an acceptor (for example, B, In, Al, or Be) may be doped as an impurity.

By making the impurity concentration of the first region 41 higher than that of the second region 42, the Schottky barrier b1 can be made lower than the Schottky barrier b2. In addition, the first region 41 and the second region 42 may be doped with different impurities. For example, the first region 41 may be doped with the donor, and the second region 42 may be doped with the acceptor.

The conductive portion 16 in FIG. 1 may be electrically connected to the first metal layer 14 and the second metal layer 15 by a conductive portion (wire or the like) (not illustrated). In addition, whether or not the conductive portion 16 is electrically connected to the first metal layer 14 and the second metal layer 15 may be switched by a switching element or the like. The conductive portion 16 in FIG. 1 is used as, for example, a field plate, suppresses local concentration of an electric field in the semiconductor element 10, and stabilizes the operation of the semiconductor element 10.

The interlayer film 17 is made of, for example, SiO₂.

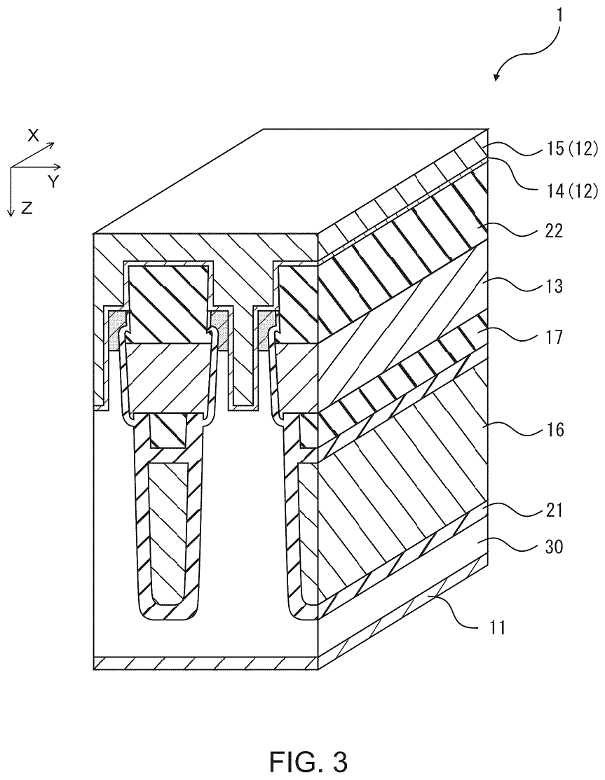

FIG. 3 is a schematic diagram of a three-dimensional structure of the semiconductor device 1 according to the embodiment of the present disclosure. FIG. 3 illustrates the third direction X intersecting the first direction Z and the second direction Y. The semiconductor device 1 may have, for example, a stripe structure in which the semiconductor element 10 extends in the third direction X. Alternatively, the semiconductor device 1 may have a dot structure in which a plurality of semiconductor elements 10 are arranged in the third direction X.

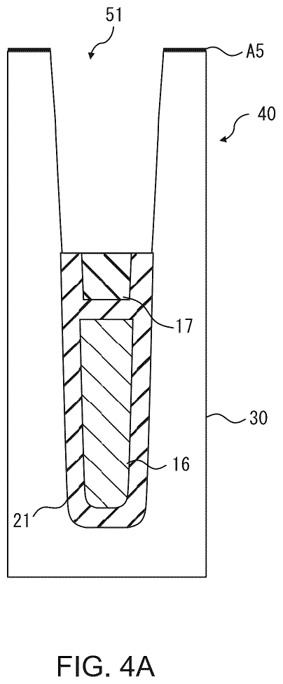

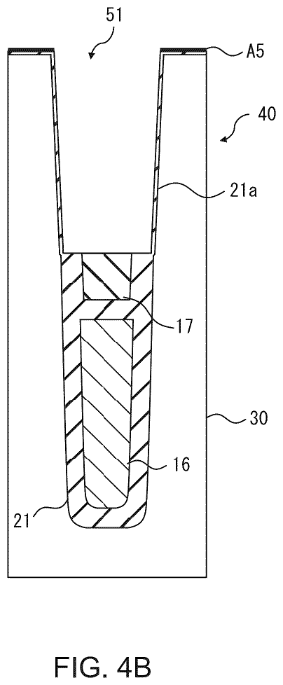

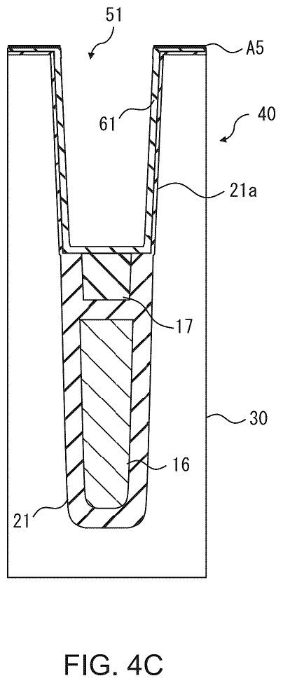

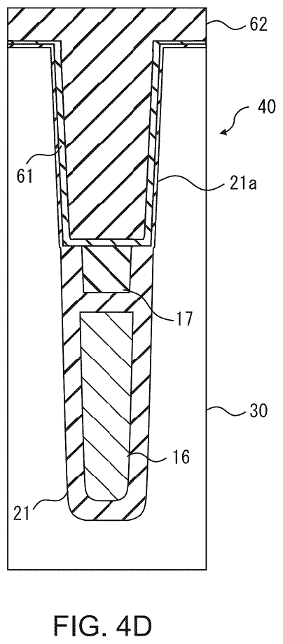

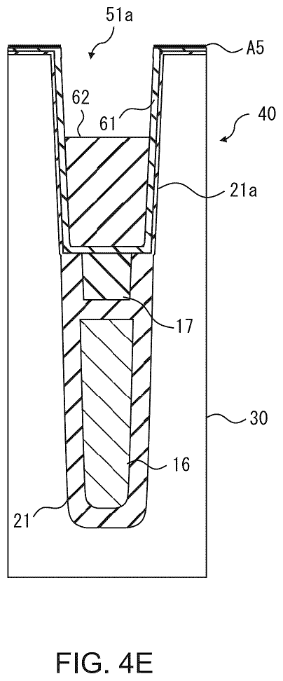

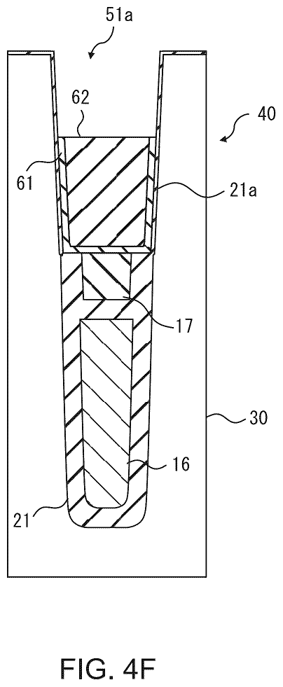

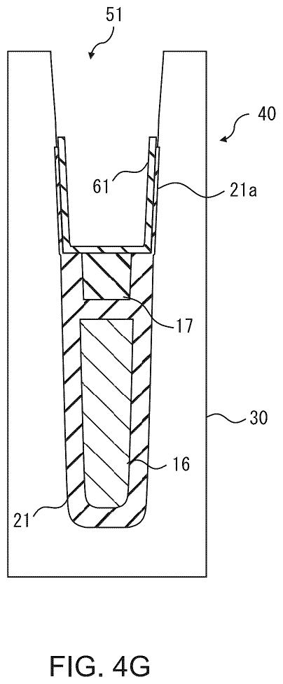

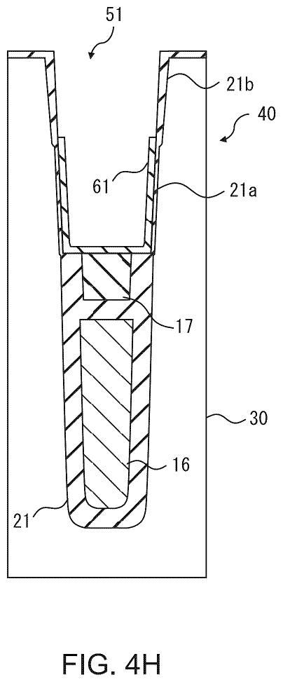

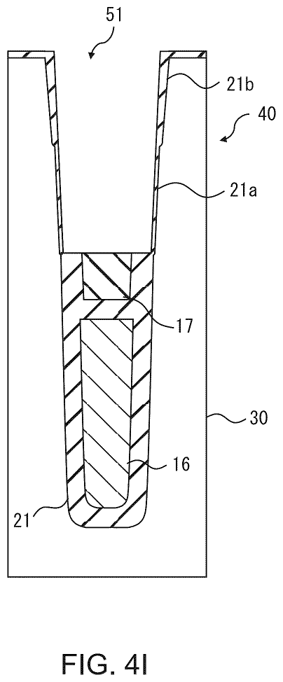

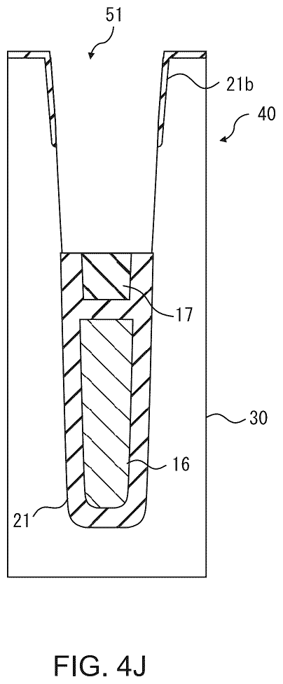

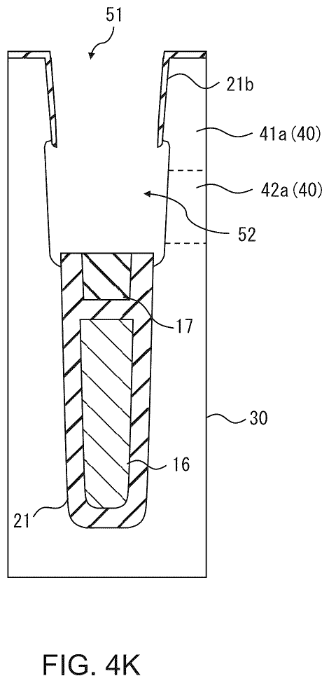

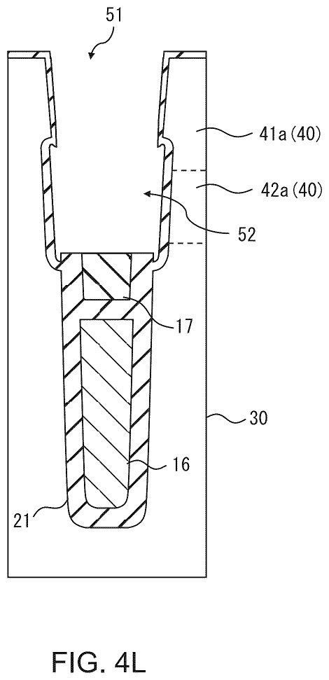

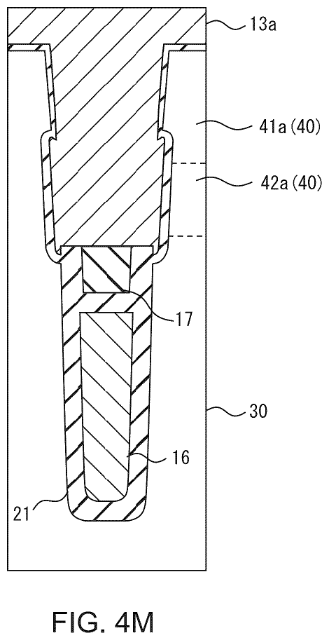

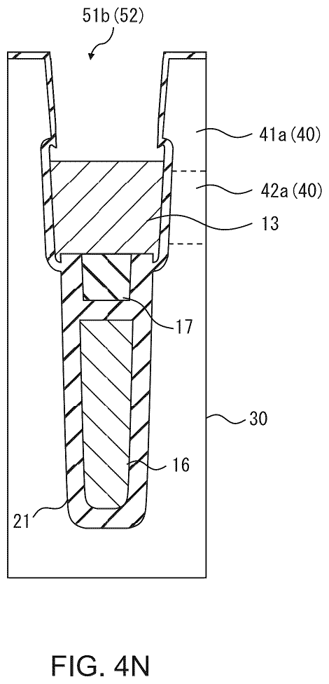

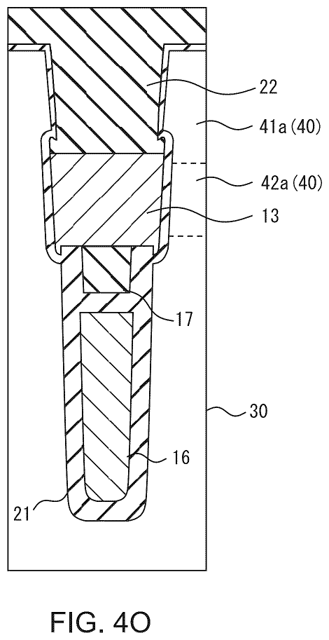

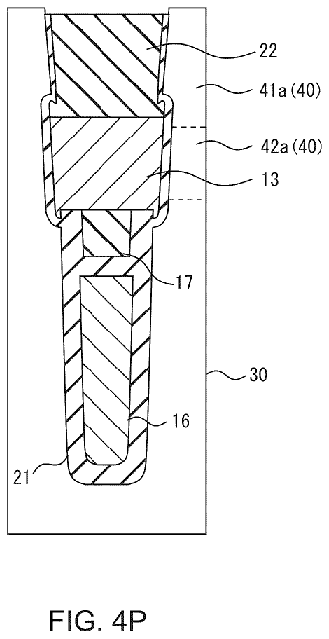

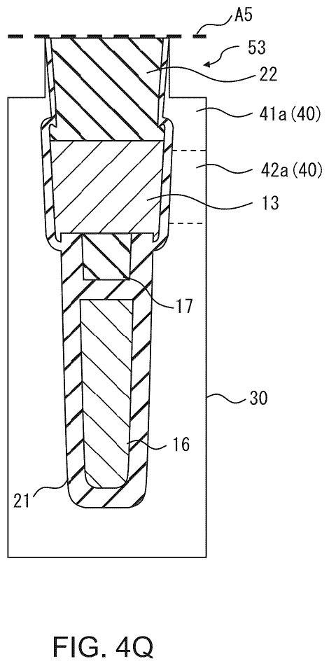

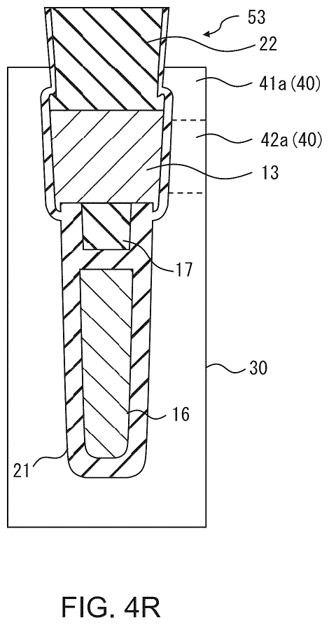

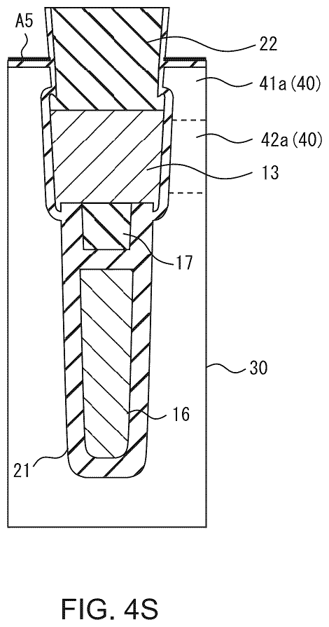

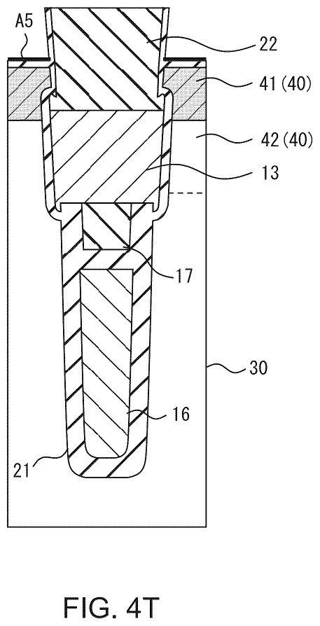

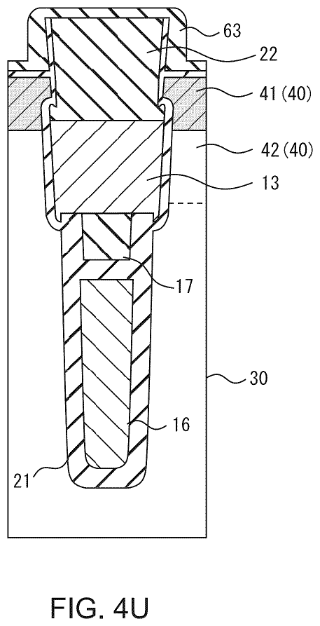

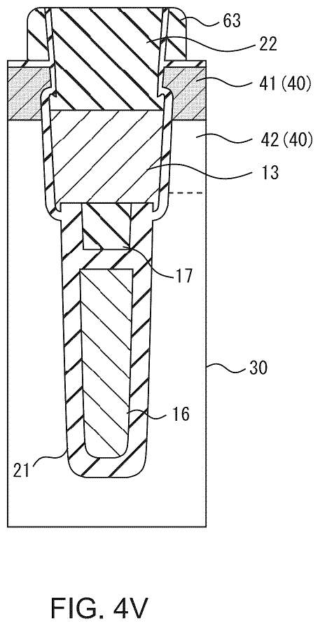

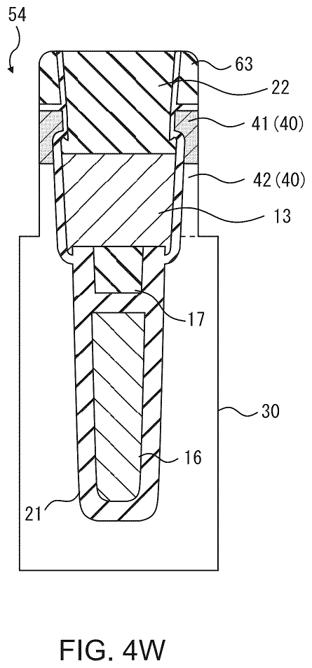

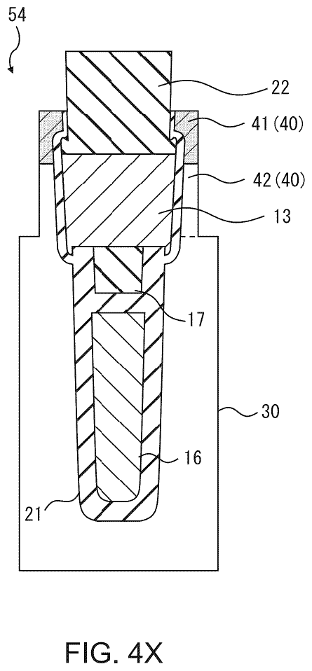

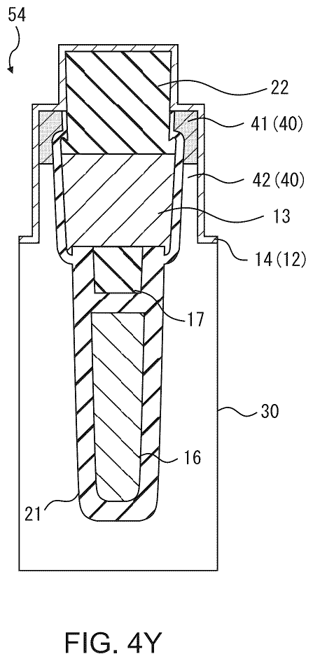

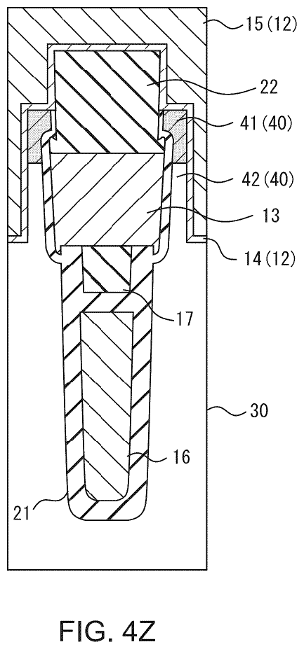

FIGS. 4A to 4Z are diagrams illustrating a manufacturing process of the semiconductor element 10 according to the embodiment of the present disclosure. FIG. 4A is a diagram illustrating a process of forming a field plate. In FIG. 4A, the semiconductor layer 30 is etched from the surface A5 side, and a trench (first trench) 51 is formed. In addition, the first insulating portion 21, the conductive portion 16, and the interlayer film 17 are embedded in a part of the trench 51. A sidewall portion of the trench 51 corresponds to the pillar portion 40 of FIG. 1.

FIG. 4B is a diagram illustrating an oxidation process of the semiconductor layer 30. In FIG. 4B, a part of the semiconductor layer 30 is oxidized, and an insulating portion 21a is formed on the surface A5 of the semiconductor layer 30 and the sidewall of the trench 51.

FIG. 4C is a diagram illustrating a film formation process of an insulating film 61. In FIG. 4C, the insulating film 61 is formed on the surface A5 of the semiconductor layer 30 and the sidewall of the trench 51. The insulating film 61 is made of, for example, SiN.

FIG. 4D is a diagram illustrating a film formation process of an insulating film 62. In FIG. 4D, the insulating film 62 is formed so as to fill the trench 51. The insulating film 62 is made of, for example, SiO₂.

FIG. 4E is a diagram illustrating an etch-back process of the insulating film 62. In FIG. 4E, a part of the insulating film 62 is removed by wet etching or the like from the surface A5 side of the semiconductor layer 30, and a trench 51a is formed. As a result, a part of the insulating film 61 is exposed to a surface layer.

FIG. 4F is a diagram illustrating a removal process of the insulating film 61. In FIG. 4F, a portion of the insulating film 61 that is not protected by the insulating film 62 is removed by wet etching or the like. As a result, a part of the insulating portion 21a is exposed to the surface layer.

FIG. 4G is a diagram illustrating a removal process of the insulating film 62 and the first insulating portion 21. In FIG. 4G, the insulating film 62 not removed in FIG. 4E is removed. In addition, a portion of the first insulating portion 21 that is not protected by the insulating film 61 is removed. As a result, the insulating portion 21a is disposed on a part of the sidewall of the trench 51.

FIG. 4H is a diagram illustrating an oxidation process of the semiconductor layer 30. In FIG. 4H, a part of the semiconductor layer 30 is oxidized, and an insulating portion 21b is formed on the surface A5 of the semiconductor layer 30 and a portion of the sidewall of the trench 51 that is not protected by the insulating film 61. In FIG. 4H, the semiconductor layer 30 is sufficiently oxidized such that the insulating portion 21b is thicker than the insulating portion 21a.

FIG. 4I is a diagram illustrating a removal process of the insulating film 61. In FIG. 4I, the insulating film 61 of FIG. 4F is removed. As a result, the insulating portion 21a is exposed to the surface layer.

FIG. 4J is a diagram illustrating an etch-back process of the insulating portions 21a and 21b. In FIG. 4J, the insulating portions 21a and 21b are etched back to such an extent that a part of the insulating portion 21b remains. In the present specification, the process of FIG. 4J is also referred to as half etch back.

FIG. 4K is a diagram illustrating a process of forming a body region 52. In FIG. 4K, a portion of the semiconductor layer 30 not protected by the insulating portion 21b (that is, the sidewall on the bottom side of the trench 51) is etched by chemical dry etching (CDE) or the like. As a result, the cylindrical body region 52 is formed in the trench 51. The body region 52 is a region swollen in the planar direction of the semiconductor layer 30. Further, in the pillar portion 40, a first region 41a and a second region 42a narrower than the first region 41a are formed.

FIG. 4L is a diagram illustrating an oxidation process of the semiconductor layer 30. In FIG. 4L, the body region 52 is oxidized, and the first insulating portion 21 is formed so as to cover the trench 51.

FIG. 4M is a diagram illustrating a process of forming the control electrode 13. In FIG. 4M, a conductive member 13a is formed so as to fill the trench 51. The conductive member 13a is made of, for example, polysilicon.

FIG. 4N is a diagram illustrating an etch-back process of the control electrode 13. In FIG. 4N, a part of the conductive member 13a is etched to form a trench 51b. As a result, the control electrode 13 is formed so as to fill a part of the body region 52 (so as to be in contact with the first insulating portion 21).

FIG. 4O is a diagram illustrating a process of forming the second insulating portion 22. In FIG. 4O, the second insulating portion 22 is formed so as to fill the trench 51b (so as to be disposed on the control electrode 13).

FIG. 4P is a diagram illustrating an etch-back process of the first insulating portion 21 and the second insulating portion 22. In FIG. 4P, the first insulating portion 21 and the second insulating portion 22 are partially etched.

FIG. 4Q is a diagram illustrating a first formation process of a mesa shape. In FIG. 4Q, the semiconductor layer 30 is etched from the surface A5 side by reactive ion etching (RIE) or the like. As a result, a mesa portion 53 is formed on the surface A5 side.

FIG. 4R is a diagram illustrating a second formation process of the mesa shape. In FIG. 4R, a side surface portion of the mesa portion 53 in the semiconductor layer 30 is etched by CDE or the like.

FIG. 4S is a diagram illustrating an oxidation process of the semiconductor layer 30. In FIG. 4S, the surface A5 of the semiconductor layer 30 is oxidized.

FIG. 4T is a diagram illustrating an impurity doping and thermal diffusion process. In FIG. 4T, impurity ions (for example, As) are doped from the oxidized surface A5 side of the semiconductor layer 30. The doped impurities are thermally diffused in the first region 41a and the second region 42a. As a result, the first region 41 is formed in the pillar portion 40 so as to face the control electrode 13 and the second insulating portion 22 with the first insulating portion 21 interposed therebetween. In addition, the second region 42 is formed so as to face the control electrode 13 with the first insulating portion 21 interposed therebetween.

FIG. 4U is a diagram illustrating a film formation process of an insulating film 63. In FIG. 4U, the insulating film 63 is formed to cover the mesa portion 53 by chemical vapor deposition (CVD) or the like. The insulating film 63 is made of, for example, SiO₂.

FIG. 4V is a diagram illustrating an etch-back process of the insulating film 63. In FIG. 4V, a part of the insulating film 63 is removed by RIE or the like.

FIG. 4W is a diagram illustrating a process of forming Trecon (Trench-Contact). A portion of the semiconductor layer 30 and the first insulating portion 21 that is not protected by the insulating film 63 is etched to form a trench (second trench) 54. The trench 54 is a trench for contact with the source electrode.

FIG. 4X is a diagram illustrating an etching process of the first insulating portion 21 and the like. In FIG. 4X, the insulating film 63 is removed, and a part of the first insulating portion 21 is etched. Note that a part of the second insulating portion 22 may be etched.

FIG. 4Y is a diagram illustrating a metal film formation process of the first metal layer 14. In FIG. 4Y, the first metal layer 14 is formed on the surfaces of the first insulating portion 21 and the semiconductor layer 30 so as to cover the sidewall of the trench 54.

FIG. 4Z is a diagram illustrating a metal film formation process of the second metal layer 15. In FIG. 4Z, the second metal layer 15 is formed so as to overlap the first metal layer 14. As a result, the semiconductor element 10 is formed. Note that the first electrode 11 may be formed, for example, in a pre-process of FIG. 4A or in a post-process of FIG. 4Z.

The shape of the body region 52 and the shape of the control electrode 13 in FIG. 4K are merely examples. If the semiconductor element 10 according to the present disclosure have the first region 41 having a large width on the first surface A1 side of the pillar portion 40 and the second region 42 having a small width on the second surface A2 side, the shape of the control electrode 13 or the like is not limited to the example of FIG. 1.

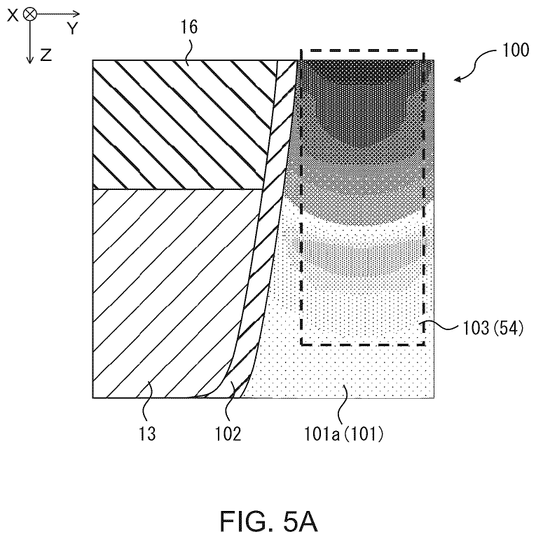

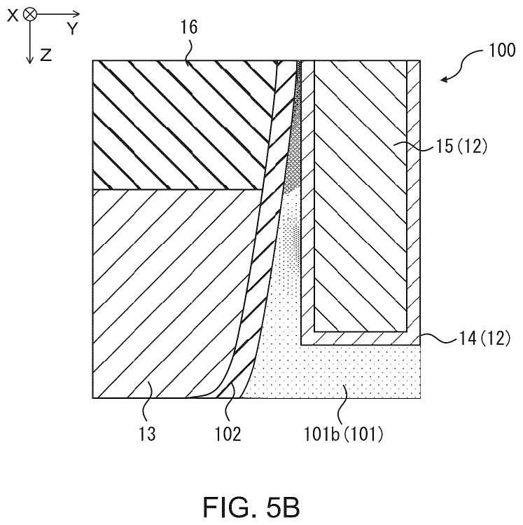

FIGS. 5A and 5B are diagrams illustrating a configuration of a semiconductor device 100 according to a comparative example. Similarly to FIG. 2, FIG. 5B is an enlarged view of a region between the control electrode 13 and the second electrode 12. FIG. 5A is a diagram illustrating a stage before the second electrode 12 is formed. The semiconductor device 100 is used as a MOSFET.

The semiconductor device 100 in FIG. 5B includes a pillar portion 101 and a first insulating portion 102 corresponding to the pillar portion 40 and the first insulating portion 21 in FIG. 2, respectively. The pillar portion 101 in FIG. 5B is different from the pillar portion 40 in FIG. 2 in that the pillar portion does not have the first region 41 having a large width on the first surface A1 side (that is, the upper side of FIG. 5B). The width of the pillar portion 101 in FIG. 5B monotonously decreases toward the first surface A1.

Therefore, in the semiconductor device 100 according to the comparative example, the width with respect to the source contact region is decreased, and the source contact resistance is increased.

Further, in a pillar portion 101a of FIG. 5A, the concentration of the impurity doped in the process of FIG. 4T is illustrated. In FIG. 5A, the darker the color, the higher the impurity concentration. As illustrated in FIG. 5A, the impurity concentration of the pillar portion 101a increases toward the upper side in FIG. 5A, and the impurity concentration increases toward the center side of the pillar portion 101a.

In addition, FIG. 5A illustrates a region 103 in which the trench 54 is formed in the process of FIG. 4W. As illustrated in FIG. 5A, the trench 54 is formed at the center of the pillar portion 101a. In addition, in order to increase the threshold voltage of the semiconductor device 100, it is necessary to sufficiently reduce the width of the pillar portion 101, so that a large portion of the pillar portion 101a is removed by the trench 54. Therefore, most of portions of the pillar portion 101a having a high impurity concentration are removed.

FIG. 5B illustrates a pillar portion 101b after the region 103 is removed. As illustrated in FIG. 5B, the impurity concentration of the pillar portion 101b is greatly reduced as compared with that of the pillar portion 101a. As a result, the source contact resistance greatly increases.

As compared with the semiconductor device 100 according to the comparative example, the semiconductor device 1 according to the present disclosure has the first region 41 having a sufficiently large width. As a result, even if the trench 54 is formed by removing a part of the first region 41 and the second region 42, a portion having a high impurity concentration can be left in the pillar portion 40, and the semiconductor device 1 can reduce the source contact resistance as compared with the semiconductor device 100.

As described above, even if the first region 41 is doped with impurities before the formation of the trench 54, a high impurity concentration can be maintained. As a result, an impurity doping process (that is, FIG. 4T) can be provided as a pre-process of the formation process (that is, FIG. 4W) of the trench 54, and the manufacturing process can be simplified.

As described above, the semiconductor device 1 according to the present disclosure includes the first region 41 on the second surface A2 side where the second electrode 12 is disposed. Since the width of the interface between the first region 41 and the first metal layer 14 is sufficiently large, the source contact resistance can be reduced.

Further, as illustrated in FIG. 4K, the first region 41 is formed by forming the body region 52 into a cylindrical shape. As a result, even when the width of the pillar portion 40 is reduced in order to increase the threshold voltage of the semiconductor device 1, the width of the first region 41 can be increased.

In addition, the first region 41 can maintain a high impurity concentration even when the trench 54 is formed after doping with impurities. As a result, in the first region 41, the source contact resistance can be reduced, the impurities can be doped in a pre-process of forming the trench 54, and the manufacturing process can be simplified.

That is, the semiconductor device 1 can achieve both an increase in the threshold voltage and a reduction in the source contact resistance.

While certain embodiments have been described, these embodiments have been presented by way of example only, and are not intended to limit the scope of the disclosures. Indeed, the novel methods and systems described herein may be embodied in a variety of other forms; furthermore, various omissions, substitutions and changes in the form of the methods and systems described herein may be made without departing from the spirit of the disclosures. The accompanying claims and their equivalents are intended to cover such forms or modifications as would fall within the scope and spirit of the disclosures.

1. A semiconductor device comprising:
a first electrode;
a second electrode disposed separately from the first electrode in a first direction;
a control electrode disposed to face the second electrode in a second direction intersecting the first direction;
a first insulating portion provided between the second electrode and the control electrode;
a semiconductor layer provided between the first electrode and the second electrode;
a first region provided between the second electrode and the first insulating portion in the semiconductor layer and connected to the second electrode by a Schottky junction; and
a second region joined to the first region, disposed on the first electrode side, connected to the second electrode by a Schottky junction, and having a smaller width in the second direction than at least a part of the first region.

2. The semiconductor device according to claim 1, wherein
the first region has a higher impurity concentration than the second region.

3. The semiconductor device according to claim 1, wherein
the semiconductor layer includes
a first surface on which the first electrode is disposed, and
a second surface on which the second electrode is disposed and which is opposite to the first surface, and
the second electrode has a convex portion extending from the second surface toward the first surface and connected to the first region and the second region by a Schottky junction.

4. The semiconductor device according to claim 3, further comprising:
a second insulating portion adjacent to the control electrode and disposed on the second surface side from the control electrode, wherein
the first region is disposed from the second surface side to at least a position reaching an interface between the control electrode and the second insulating portion.

5. The semiconductor device according to claim 4, wherein
a width of the control electrode in the second direction is larger than a width of at least a part of a portion of the second insulating portion facing the second electrode in the second direction.

6. The semiconductor device according to claim 4, wherein
a width in the second direction of at least a part of a portion facing the second insulating portion in the first region is larger than a width in the second direction in the second region.

7. The semiconductor device according to claim 1, wherein
the second electrode includes
a first metal layer, and
a second metal layer provided between the first metal layer and the semiconductor layer, having a higher work function than the first metal layer, and connected to the first region and the second region by a Schottky junction.

8. The semiconductor device according to claim 7, wherein
the first metal layer contains at least one of titanium, tungsten, molybdenum, tantalum, zirconium, aluminum, tin, vanadium, rhenium, osmium, iridium, platinum, lead, rhodium, ruthenium, niobium, strontium, cobalt, or hafnium.

9. The semiconductor device according to claim 7, wherein
the second metal layer contains at least one of aluminum, copper, molybdenum, tungsten, tantalum, cobalt, ruthenium, titanium, or platinum.

10. The semiconductor device according to claim 7, wherein
the first metal layer contains at least one of cobalt or platinum, and
the second metal layer contains tungsten.

11. The semiconductor device according to claim 1, further comprising:
a field plate disposed between the control electrode and the first electrode.

12. The semiconductor device according to claim 1, wherein
the first electrode, the second electrode, the control electrode, the first insulating portion, the semiconductor layer, the first region, and the second region all extend in a third direction orthogonal to the first direction and the second direction.

13. The semiconductor device according to claim 1, wherein
the first electrode is a drain electrode, the second electrode is a source electrode, and the control electrode is a gate electrode that controls a current flowing between the source electrode and the drain electrode.

14. The semiconductor device according to claim 13, wherein
the first region includes a source contact region, and
the second region includes a channel region.

15. The semiconductor device according to claim 1, wherein
the semiconductor layer contains at least one of arsenic, phosphorus, or tin.

16. The semiconductor device according to claim 15, wherein
the first region and the second region contain at least one of arsenic, phosphorus, antimony, or magnesium.

17. The semiconductor device according to claim 1, wherein
the semiconductor layer contains boron.

18. The semiconductor device according to claim 17, wherein
the first region and the second region contain at least one of boron, indium, aluminum, or beryllium.

19. A method for manufacturing a semiconductor device, comprising:
forming a first trench from a principal surface of a semiconductor layer;
etching a sidewall on a bottom side of the first trench to form a body portion swollen in a planar direction;
forming a first insulating portion on a surface of the body portion;
forming a control electrode so as to be in contact with the first insulating portion;
forming a second insulating portion on the control electrode;
forming a first region by implanting impurity ions into the semiconductor layer so as to face the control electrode and the second insulating portion with the first insulating portion interposed therebetween; and
forming a second region between the semiconductor layer and the first region and a first metal layer connected to the first region by a Schottky junction.

20. The method for manufacturing a semiconductor device according to claim 19, wherein
a second trench is formed by removing a part of the first region and a part of the second region,
the first metal layer is formed so as to cover a sidewall of the second trench, and
a second metal layer is formed on the first metal layer.
